(19) United States
(12) Patent Application Publication
(10) Pub. No.: US 2020/0176511 A1
(43) Pub. Date: Jun. 4, 2020

(54) SEMICONDUCTOR DEVICE INCLUDING SPIN-ORBIT TORQUE LINE

(71) Applicant: Samsung Electronics Co., Ltd., Suwon-si (KR)

(72) Inventors: Jeong Heon PARK, Hwaseong-si (KR); WHAN KYUN KIM, Hwaseong-si (KR); JUN MYEONG LEE, Hwaseong-si (KR); JUN HO JEONG, Hwaseong-si (KR); WOONG HWAN PI, Hwaseong-si (KR)

(21) Appl. No.: 16/413,075

(22) Filed: May 15, 2019

(30) Foreign Application Priority Data
Dec. 3, 2018 (KR) 10-2018-0153469

(51) Int. Cl. H01L 27/22; G11C 11/18; H01L 43/06; H01L 43/08; H01L 43/10; G11C 11/16

(52) U.S. Cl. CPC H01L 27/222; G11C 11/18; G11C 11/161; H01L 43/08; H01L 43/10; H01L 43/06

(57) ABSTRACT

Semiconductor devices may include a first memory cell on a substrate and a second memory cell on the substrate and adjacent to the first memory cell. The first memory cell may include a first reference layer, a first storage layer, a first tunnel layer between the first reference layer and the first storage layer, and a first spin-orbit torque (SOT) line in contact with the first storage layer. The second memory cell may include a second reference layer, a second storage layer, a second tunnel layer between the second reference layer and the second storage layer, a second SOT line adjacent to the second storage layer, and an enhancing layer between the second storage layer and the second SOT line.

### CROSS REFERENCE TO RELATED APPLICATION

This U.S. non-provisional patent application claims priority under 35 U.S.C. § 119 to Korean Patent Application No. 10-2018-0153469, filed on Dec. 3, 2018, in the Korean Intellectual Property Office (KIPO), the disclosure of which is incorporated herein by reference in its entirety.

### FIELD

The present disclosure generally relates to the field of electronics and, more particularly, to a semiconductor device including a spin-orbit torque (SOT) line, a method of operating the semiconductor device, and a method of forming the semiconductor device.

### BACKGROUND

It may be beneficial to include both a memory device having excellent data retention characteristics and a memory device having a high operation speed in a single electronic device. When the memory device having the excellent data retention characteristics and the memory device having the high operation speed are formed in different chips and then mounted in a single electronic device, it may not be easy to make the electronic device light, thin, and small.

### SUMMARY

Example embodiments of the inventive concept are directed to a semiconductor device including memory devices having different characteristics, a method of operating the semiconductor device, and a method of forming the semiconductor device.

According to example embodiments, semiconductor devices may include a first memory cell on a substrate and a second memory cell on the substrate and adjacent to the first memory cell. The first memory cell may include a first reference layer, a first storage layer, a first tunnel layer between the first reference layer and the first storage layer, and a first spin-orbit torque (SOT) line in contact with the first storage layer. The second memory cell may include a second reference layer, a second storage layer, a second tunnel layer between the second reference layer and the second storage layer, a second SOT line adjacent to the second storage layer, and an enhancing layer between the second storage layer and the second SOT line.

According to example embodiments, semiconductor devices may include a first memory cell on a substrate and a second memory cell that is on the substrate and is adjacent to the first memory cell. The first memory cell may include a first reference layer, a first storage layer, a first tunnel layer between the first reference layer and the first storage layer, and a first spin-orbit torque (SOT) line in contact with the first storage layer. The second memory cell may include a second reference layer, a second storage layer, a second tunnel layer between the second reference layer and the second storage layer, and a second SOT line in contact with the second storage layer. The second SOT line may include a material having a higher spin-orbit coupling, a larger spin hall angle, or a higher spin/electrical current conductivity than the first SOT line.

According to example embodiments, semiconductor devices may include a substrate including a first region and a second region adjacent to the first region, a first memory cell in the first region on the substrate, and a second memory cell in the second region on the substrate. The first memory cell may include a first reference layer, a first storage layer, a first tunnel layer between the first reference layer and the first storage layer, and a first spin-orbit torque (SOT) line in contact with the first storage layer. The second memory cell may include a second reference layer, a second storage layer, a second tunnel layer between the second reference layer and the second storage layer, a second SOT line adjacent to the second storage layer, and an enhancing layer between the second storage layer and the second SOT line.

### BRIEF DESCRIPTION OF THE DRAWINGS

FIGS. 1 to 12 are cross-sectional views illustrating semiconductor devices according to some embodiments of the inventive concept.

FIGS. 13 to 16 are layouts illustrating semiconductor devices according to some embodiments of the inventive concept.

FIG. 17 is a perspective view illustrating a semiconductor device according to some embodiments of the inventive concept.

FIG. 18 is a perspective view of a portion of a semiconductor device according to some embodiments of the inventive concept.

FIGS. 19 and 20 are schematic views illustrating methods of operating a semiconductor device according to some embodiments of the inventive concept.

### DETAILED DESCRIPTION

FIGS. 1 to 12 are cross-sectional views illustrating semiconductor devices according to some embodiments of the inventive concept. The semiconductor device according to some embodiments of the inventive concept may include a non-volatile memory device such as a magnetoresistive random access memory (MRAM) or a cross-point (X-point) memory. In some embodiments, the semiconductor device may include an embedded MRAM (eMRAM). In some embodiments, the semiconductor device may include in-plane magnetic tunnel junction-MRAM (iMTJ-MRAM) and/or perpendicular MTJ-MRAM (pMTJ-MRAM).

Referring to FIG. 1, the semiconductor device according to some embodiments of the inventive concept may include a first memory cell 69 disposed in a first region 10 on a substrate 51 and a second memory cell 79 disposed in a second region 20 on the substrate 51. The second memory cell 79 may be disposed adjacent to the first memory cell 69. In some embodiments, the first memory cell 69 may have a longer data retention time than the second memory cell 79. The second memory cell 79 may have a higher write speed than the first memory cell 69.

The first memory cell 69 may include a first spin-orbit torque (SOT) line 61, a first MTJ 67, and a first electrode 68. The first MTJ 67 may include a first storage layer 63, a first tunnel layer 64, and a first reference layer 65. The second memory cell 79 may include a second SOT line 71, an enhancing layer 72, a second MTJ 77, and a second electrode 78. The second MTJ 77 may include a second storage layer 73, a second tunnel layer 74, and a second reference layer 75.

The substrate 51 may include a semiconductor substrate such as a wafer (e.g., a silicon wafer, a silicon on insulator (SOI) wafer). Various kinds of active/passive elements, such as transistors and interconnections, may be further disposed in the substrate 51 and/or on the substrate 51, but descriptions thereof will be omitted for brevity.

In some embodiments, the substrate 51 including the first region 10 and the second region 20 may be a portion of a single wafer (e.g., a single wafer of single crystal semiconductor material), and more specifically, the substrate 51 including the first region 10 and the second region 20 may be a portion of a single wafer within a single chip surrounded by scribe lines. Accordingly, the substrate 51 may have a unitary or monolithic structure and may have a continuous crystal structure. The first region 10 and the second region 20 may be connected to each other, in some embodiments, directly connected to each other without any intervening element, and no discontinuity of crystal structure may exist between the first region 10 and the second region 20.

The first SOT line 61 and the second SOT line 71 may be disposed on the substrate 51. Bottom surfaces of the first SOT line 61 and the second SOT line 71 may be substantially coplanar with each other. The second SOT line 71 may have a smaller thickness than the first SOT line 61. In some embodiments, the second SOT line 71 may be thinner than the first SOT line 61, as illustrated in FIG. 1. Each of the first SOT line 61 and the second SOT line 71 may include a material having a low electrical resistance. Each of the first SOT line 61 and the second SOT line 71 may include a normal metal. The second SOT line 71 may include substantially the same material layer as the first SOT line 61. For example, the first SOT line 61 and the second SOT line 71 may include tungsten (W).

The enhancing layer 72 may be disposed on the second SOT line 71. One surface of the enhancing layer 72 may be in direct contact with the second SOT line 71. A top surface of the enhancing layer 72 (i.e., a surface of the enhancing layer 72 facing the second MTJ 77) and a top surface of the first SOT line 61 (i.e., a surface of the first SOT line 61 facing the first MTJ 67) may be substantially coplanar with each other. The enhancing layer 72 may be referred to as a spin-orbit coupling enhancing surface layer. The enhancing layer 72 may include a material having a high spin-orbit coupling, a large spin hall angle, or a high spin/electrical current conductivity.

In some embodiments, a thickness of the enhancing layer 72 may be smaller than that of the second SOT line 71, as illustrated in FIG. 1. The enhancing layer 72 may include a material having a higher spin-orbit coupling, a larger spin hall angle, or a higher spin/electrical current conductivity than the second SOT line 71. The enhancing layer 72 may include tungsten (W), platinum (Pt), tantalum (Ta), tantalum oxide (TaO), platinum oxide (PtO), tungsten oxide (WO), bismuth antimonide (BiSb), bismuth selenide (BiSe), hafnium (Hf), hafnium oxide (HfO), gold (Au), copper gold (CuAu), copper lead (CuPb), copper platinum (CuPt), copper bismuth (CuBi), copper iridium (CuIr), or a combination thereof. For example, the enhancing layer 72 may include bismuth antimonide.

The first MTJ 67 may be disposed on the first SOT line 61. The first electrode 68 may be disposed on the first MTJ 67. The first storage layer 63, the first tunnel layer 64, and the first reference layer 65 may be sequentially stacked on the first SOT line 61. The second MTJ 77 may be disposed on the enhancing layer 72. The second electrode 78 may be disposed on the second MTJ 77. The second storage layer 73, the second tunnel layer 74, and the second reference layer 75 may be sequentially stacked on the enhancing layer 72. The second MTJ 77 may have a smaller width than the first MTJ 67. The second storage layer 73 may have a smaller width than the first storage layer 63.

Each of the first reference layer 65, the second reference layer 75, the first storage layer 63, and the second storage layer 73 may include at least one magnetic layer. Each of the first reference layer 65, the second reference layer 75, the first storage layer 63, and the second storage layer 73 may include at least one synthetic antiferromagnetic (SAF) structure. The SAF structure may include two magnetic layers and a spacer layer interposed between the two magnetic layers. For example, the SAF structure may include a cobalt iron boron (CoFeB) layer, a ruthenium (Ru) layer, and a cobalt iron (CoFe) layer, which are sequentially stacked.

Each of the first storage layer 63 and the second storage layer 73 may include a free layer. In some embodiments, each of the first storage layer 63 and the second storage layer 73 may include cobalt iron (CoFe), cobalt iron boron (CoFeB), or a combination thereof. Each of the first reference layer 65 and the second reference layer 75 may include a pinned layer, a fixed layer, or a combination thereof.

Each of the first tunnel layer 64 and the second tunnel layer 74 may correspond to a tunnel barrier layer. Each of the first tunnel layer 64 and the second tunnel layer 74 may include a metal oxide such as magnesium oxide (MgO), ruthenium oxide (RuO), vanadium oxide (VO), tungsten oxide (WO), tantalum oxide (TaO), hafnium oxide (HfO), molybdenum oxide (MoO), or a combination thereof. For example, each of the first tunnel layer 64 and the second tunnel layer 74 may be a MgO layer. Each of the first electrode 68 and the second electrode 78 may include titanium (Ti), titanium nitride (TiN), tantalum (Ta), tantalum nitride (TaN), tungsten (W), tungsten nitride (WN), or a combination thereof.

In some embodiments, the first storage layer 63 may be disposed opposite the first reference layer 65. In some embodiments, the first storage layer 63 and the first reference layer 65 are on opposing sides of the first tunnel layer 64, respectively, as illustrated in FIG. 1. The first tunnel layer 64 may be disposed between the first reference layer 65 and the first storage layer 63. The first SOT line 61 may be in contact with the first storage layer 63. The second storage layer 73 may be disposed opposite the second reference layer 75. In some embodiments, the second storage layer 73 and the second reference layer 75 are on opposing sides of the second tunnel layer 74, respectively, as illustrated in FIG. 1. The second tunnel layer 74 may be disposed between the second reference layer 75 and the second storage layer 73. The second SOT line 71 may be disposed adjacent to the second storage layer 73. The enhancing layer 72 may be disposed between the second storage layer 73 and the second SOT line 71.

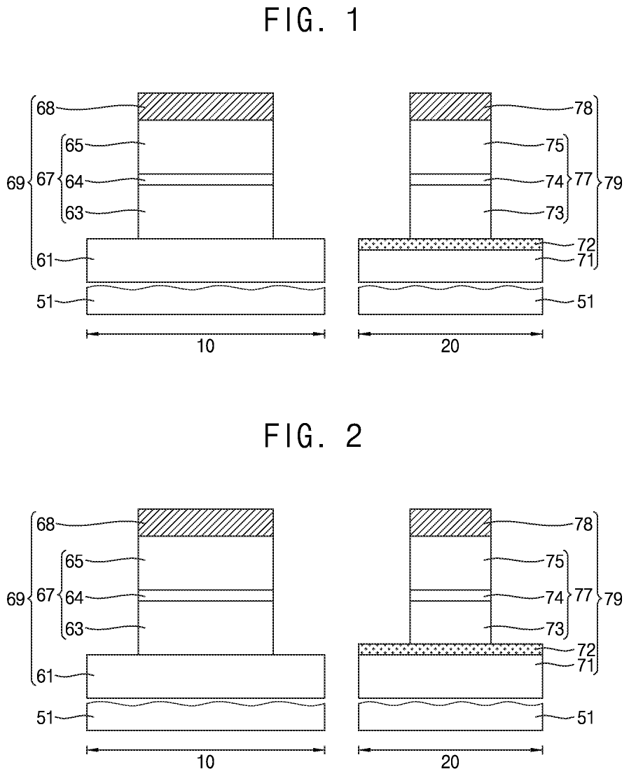

Referring to FIG. 2, the second SOT line 71 may have substantially the same thickness as the first SOT line 61. The top surface of the enhancing layer 72 (i.e., a surface of the enhancing layer 72 facing the second MTJ 77) may be disposed at a higher level than the top surface of the first SOT line 61 (i.e., a surface of the first SOT line 61 facing the first MTJ 67). In some embodiments, a surface of the enhancing layer 72 facing the second MTJ 77 may be at a higher level than a surface of the first SOT line 61 facing the first MTJ 67 relative to the substrate 51, as illustrated in FIG. 2.

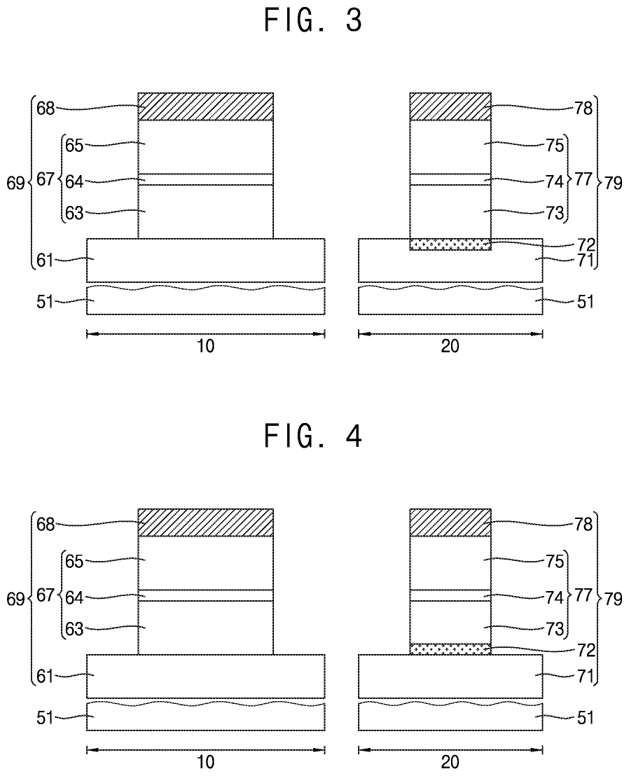

Referring to FIG. 3, the enhancing layer 72 may be disposed under the second MTJ 77 and may be overlapped by the second MTJ 77. Side surfaces of the enhancing layer 72 may be aligned with side surfaces of the second MTJ 77, respectively. The side surfaces of the enhancing layer 72 and side surfaces of the second storage layer 73 may be substantially coplanar with each other. The enhancing layer 72 may be disposed in the second SOT line 71. The top surface of the enhancing layer 72 and a top surface of the second SOT line 71 may be substantially coplanar with each other. The top surfaces of the enhancing layer 72 and the second SOT line 71 may be at substantially the same level as the top surface of the first SOT line 61.

Referring to FIG. 4, the enhancing layer 72 may be disposed on the second SOT line 71. The second SOT line 71 may have substantially the same thickness as the first SOT line 61. The top surface of the enhancing layer 72 may be at a higher level than the top surface of the first SOT line 61. The side surfaces of the enhancing layer 72 and the side surfaces of the second storage layer 73 may be substantially coplanar with each other.

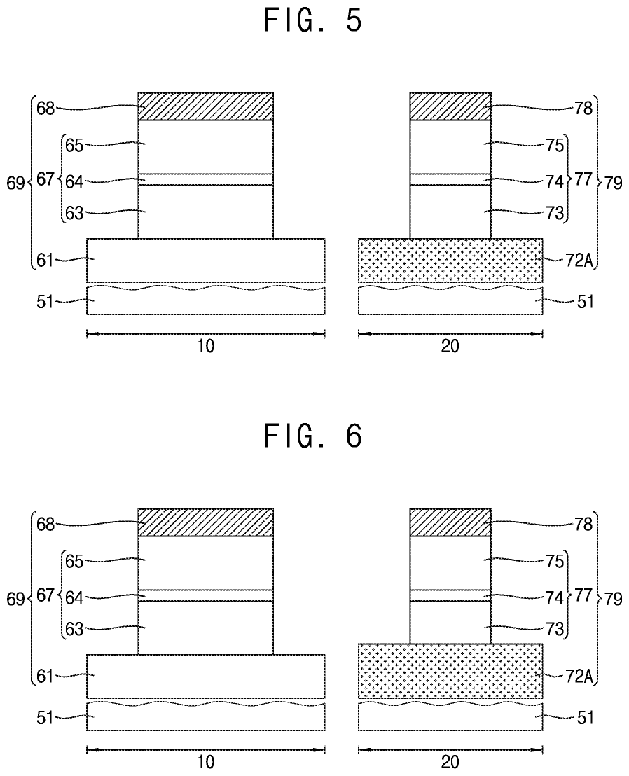

Referring to FIG. 5, the second memory cell 79 may include the second reference layer 75, the second storage layer 73 disposed opposite the second reference layer 75, the second tunnel layer 74 disposed between the second reference layer 75 and the second storage layer 73, and an enhancing layer 72A in contact with the second storage layer 73. The enhancing layer 72A may take the place of the second SOT line 71. Accordingly, it will be understood that the enhancing layer 72A can be referred to as “a second SOT line.” The enhancing layer 72A may include a material having a higher spin-orbit coupling, a larger spin hall angle, or a higher spin/electrical current conductivity than the first SOT line 61. The enhancing layer 72A may have substantially the same thickness as the first SOT line 61.

Referring to FIG. 6, the enhancing layer 72A may take the place of the second SOT line 71. The enhancing layer 72A may be thicker than the first SOT line 61. A top surface of the enhancing layer 72A may be disposed at a higher level than the top surface of the first SOT line 61. In some embodiments, a surface of the enhancing layer 72A facing the second MTJ 77 may be at a higher level than a surface of the first SOT line 61 facing the first MTJ 67 relative to the substrate 51, as illustrated in FIG. 6.

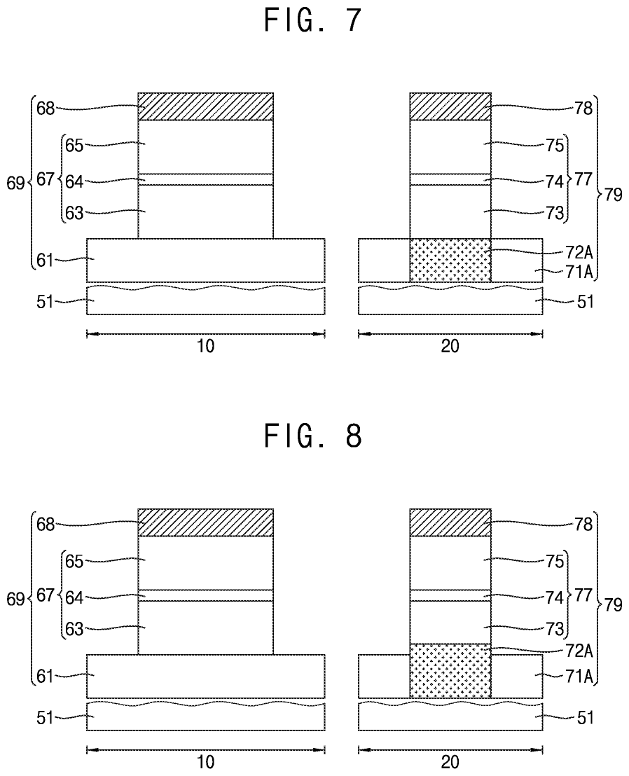

Referring to FIG. 7, the enhancing layer 72A may be disposed in a second SOT line 71A. The enhancing layer 72A may have substantially the same thickness as the second SOT line 71A. The enhancing layer 72A may be disposed under the second MTJ 77 and may be overlapped by the second MTJ 77. The top surface of the enhancing layer 72A and a top surface of the second SOT line 71A may be substantially coplanar with each other. Side surfaces of the enhancing layer 72A and the side surfaces of the second storage layer 73 may be substantially coplanar with each other.

Referring to FIG. 8, the enhancing layer 72A may be thicker than the second SOT line 71A. The top surface of the enhancing layer 72A may be at a higher level than the top surface of the second SOT line 71A. In some embodiments, the enhancing layer 72A may protrude beyond the top surface of the second SOT line 71A toward the second MTJ 77, as illustrated in FIG. 8.

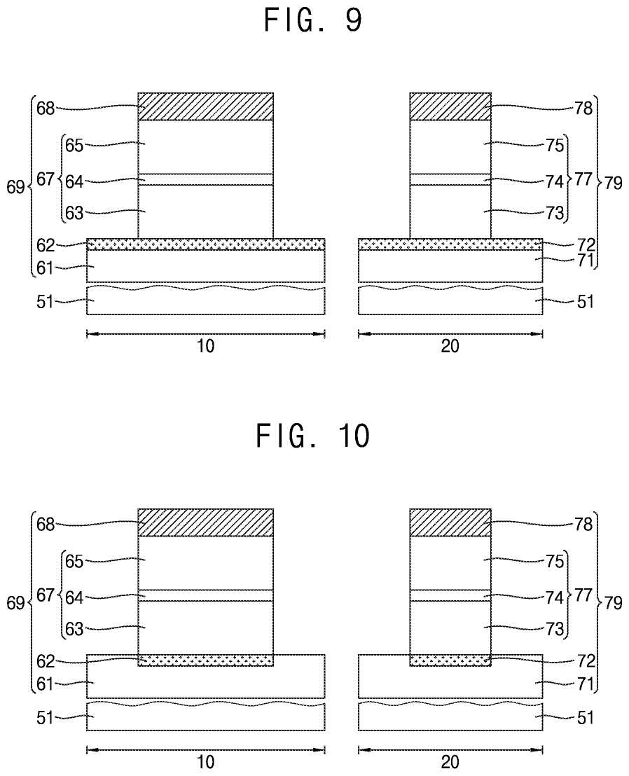

Referring to FIG. 9, a first enhancing layer 72 may be disposed on the second SOT line 71. In some embodiments, the first enhancing layer 72 may be referred to as an enhancing layer. A second enhancing layer 62 may be disposed on the first SOT line 61. The second enhancing layer 62 may cover the first SOT line 61. The second enhancing layer 62 may be disposed between the first SOT line 61 and the first storage layer 63. The second enhancing layer 62 may include the same material as the first enhancing layer 72. The second enhancing layer 62 may have substantially the same thickness as the first enhancing layer 72. It will be understood that “an element A covers an element B” (or similar language) means that the element A is on the element B but does not necessarily mean that the element A covers the element B entirely.

Referring to FIG. 10, the second enhancing layer 62 may be disposed in the first SOT line 61. A top surface of the second enhancing layer 62 and the top surface of the first SOT line 61 may be substantially coplanar with each other. The second enhancing layer 62 may be disposed under the first storage layer 63 and may be overlapped by the first storage layer 63. Side surfaces of the second enhancing layer 62 and side surfaces of the first storage layer 63 may be substantially coplanar with each other.

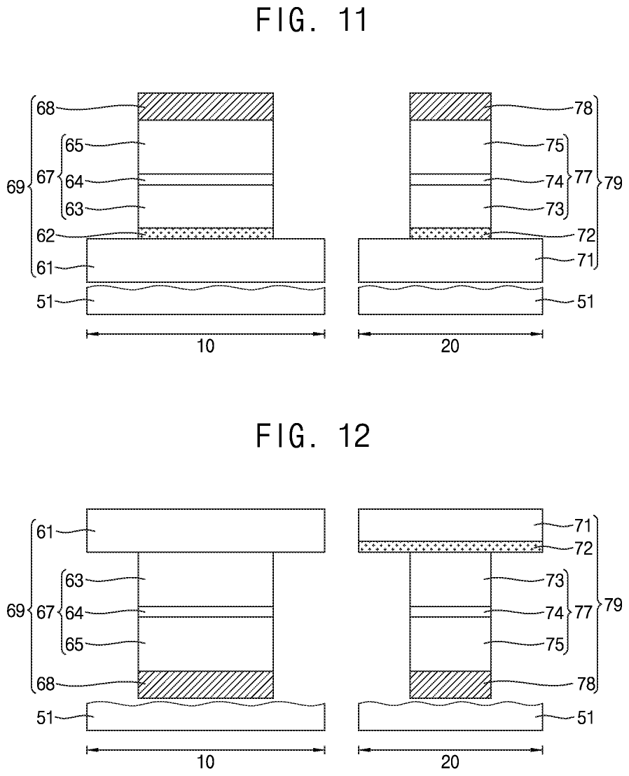

Referring to FIG. 11, the second enhancing layer 62 may be disposed on the first SOT line 61. The second enhancing layer 62 may be disposed under the first storage layer 63 and may be overlapped by the first storage layer 63. The side surfaces of the second enhancing layer 62 and the side surfaces of the first storage layer 63 may be substantially coplanar with each other.

Referring to FIG. 12, the first electrode 68, the first reference layer 65, the first tunnel layer 64, and the first storage layer 63 may be sequentially stacked in the first region 10 on the substrate 51. The first SOT line 61 may be disposed on the first storage layer 63. The second electrode 78, the second reference layer 75, the second tunnel layer 74, and the second storage layer 73 may be sequentially stacked in the second region 20 on the substrate 51. The enhancing layer 72 may be disposed on the second storage layer 73. The second SOT line 71 may be disposed on the enhancing layer 72.

FIGS. 13 to 16 are layouts illustrating semiconductor devices according to some embodiments of the inventive concept.

Referring to FIG. 13, a substrate 51 including a first region 10 and a second region 20 adjacent to the first region 10 may be provided. A plurality of first memory cells 69, each of which is similar to that described with reference to FIGS. 1 to 12, may be repeatedly arranged in row and column directions in the first region 10 on the substrate 51. A plurality of second memory cells 79, each of which is similar to that described with reference to FIGS. 1 to 12, may be repeatedly arranged in row and column directions in the second region 20 on the substrate 51. The second region 20 may be disposed outside the first region 10. The second region 20 may be disposed closer to an edge of the substrate 51 than the first region 10.

External physical/chemical variations may have a relatively large effect on the edge of the substrate 51. The first memory cell 69 may have a longer data retention time than the second memory cell 79. The second memory cell 79 may have a higher write speed than the first memory cell 69. The second memory cell 79 may be disposed closer to the edge of the substrate 51 than the first memory cell 69. The first memory cell 69 may be disposed closer to a center of the substrate 51 than the second memory cell 79.

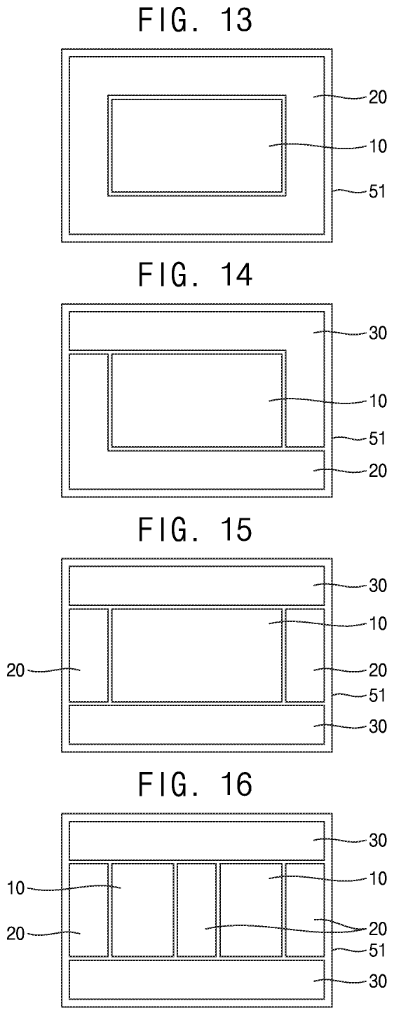

Referring to FIG. 14, a substrate 51 including a first region 10, a second region 20, and a third region 30 may be provided. The third region 30 may include control circuits connected to the first memory cell 69 and the second memory cell 79. The second region 20 and the third region 30 may be disposed outside the first region 10.

Referring to FIG. 15, a pair of third regions 30 may be disposed on opposing sides of the first region 10. A pair of second regions 20 may be disposed between the pair of third regions 30. The pair of second regions 20 may be disposed opposite with respect to the first region 10. The first region 10 may be surrounded by the pair of third regions 30 and the pair of second regions 20.

Referring to FIG. 16, the pair of third regions 30 may be disposed on opposing sides of one of the first regions 10. A plurality of first regions 10 and a plurality of second regions 20 may be alternately disposed between the pair of third regions 30. Each of the plurality of first regions 10 may be surrounded by the pair of third regions 30 and two second regions 20 of the plurality of second regions 20.

FIG. 17 is a perspective view illustrating a semiconductor device according to some embodiments of the inventive concept.

Referring to FIG. 17, a first MTJ 67 may be disposed on a first SOT line 61. A first storage layer 63, a first tunnel layer 64, and a first reference layer 65 may be sequentially stacked on the first SOT line 61. In some embodiments, the first storage layer 63, the first tunnel layer 64, and the first reference layer 65 are stacked along a vertical direction (e.g., a direction Z), as illustrated in FIG. 17. An enhancing layer 72 may be disposed on a second SOT line 71. A second MTJ 77 may be disposed on the enhancing layer 72. A second storage layer 73, a second tunnel layer 74, and a second reference layer 75 may be sequentially stacked on the enhancing layer 72. The second MTJ 77 may have a smaller width than the first MTJ 67. The second storage layer 73 may have a smaller width than the first storage layer 63. A width of each of the second SOT line 71 and the enhancing layer 72 may be smaller than a width of the first SOT line 61. In some embodiments, the second MTJ 77 may have a width in a horizontal direction (e.g., a direction X or a direction Y) narrower than a width of the first MTJ 67 in the horizontal direction, as illustrated in FIG. 17. In some embodiments, each of the second SOT line 71 and the enhancing layer 72 may have a width in a horizontal direction (e.g., a direction X or a direction Y) narrower than a width of the first SOT line 61 in the horizontal direction, as illustrated in FIG. 17. The vertical direction is perpendicular to the horizontal direction.

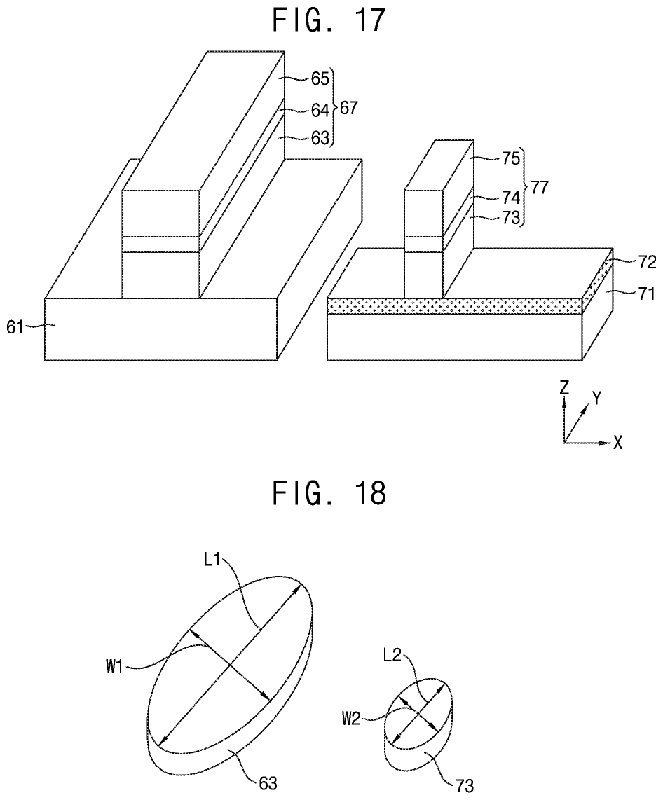

FIG. 18 is a perspective view of a portion of a semiconductor device according to some embodiments of the inventive concept.

Referring to FIG. 18, a second storage layer 73 may have a smaller volume than a first storage layer 63. The second storage layer 73 may have a lower ratio of a major axis to a minor axis than the first storage layer 63.

In some embodiments, a major axis of the first storage layer 63 may have a first length L1. A minor axis of the first storage layer 63 may have a first width W1. A major axis of the second storage layer 73 may have a second length L2. A minor axis of the second storage layer 73 may have a second width W2. A ratio of the second length L2 to the second width W2 may be lower than a ratio of the first length L1 to the first width W1. Although FIG. 18 shows that each of the first storage layer 63 and the second storage layer 73 has an oval shape, it will be understood that each of the first storage layer 63 and the second storage layer 73 can have various shapes (e.g., a rectangular shape).

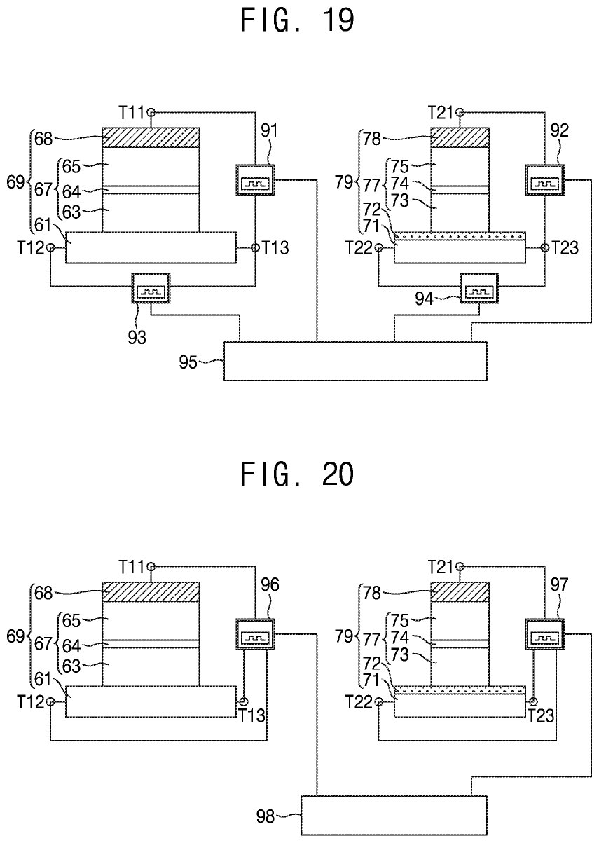

FIGS. 19 and 20 are schematic views illustrating methods of operating a semiconductor device according to some embodiments of the inventive concept.

Referring to FIG. 19, the semiconductor device according to some embodiments of the inventive concept may include a plurality of terminals T11, T12, T13, T21, T22, and T23, a first circuit 91, a second circuit 92, a third circuit 93, a fourth circuit 94, a control device 95, a first memory cell 69, and a second memory cell 79. Each of the first memory cell 69 and the second memory cell 79 may have various configurations similar to that described with reference to FIGS. 1 to 18. Each of the plurality of terminals T11, T12, T13, T21, T22, and T23 may include an electrical terminal. The plurality of terminals T11, T12, T13, T21, T22, and T23 may include a first terminal T11 connected to a first electrode 68, a second terminal T12 connected to a first end of a first SOT line 61, a third terminal T13 connected to a second end of the first SOT line 61, a fourth terminal T21 connected to a second electrode 78, a fifth terminal T22 connected to a first end of a second SOT line 71, and a sixth terminal T23 connected to a second end of the second SOT line 71.

The first circuit 91 may be connected to the first terminal T11 and the third terminal T13. The second circuit 92 may be connected to the fourth terminal T21 and the sixth terminal T23. Each of the first circuit 91 and the second circuit 92 may correspond to an MTJ circuit. The third circuit 93 may be connected to the second terminal T12 and the third terminal T13. The fourth circuit 94 may be connected to the fifth terminal T22 and the sixth terminal T23. Each of the third circuit 93 and the fourth circuit 94 may correspond to a spin hall effect (SHE) circuit. Each of the first circuit 91, the second circuit 92, the third circuit 93, and the fourth circuit 94 may be connected to the control device 95.

Referring back to FIG. 17, when the first reference layer 65 and the first storage layer 63 have a parallel magnetic polarization, the first MTJ 67 may exhibit a low-resistance state. The low-resistance state may correspond to data “0.” When the first reference layer 65 and the first storage layer 63 have an anti-parallel magnetic polarization, the first MTJ 67 may exhibit a high-resistance state. The high-resistance state may correspond to data “1.” The second MTJ 77 may exhibit the low-resistance state or the high-resistance state according to the magnetic polarization of the second reference layer 75 and the second storage layer 73. A non-volatile memory device may be implemented using a spin polarized current of each of the first MTJ 67 and the second MTJ 77.

A magnetic polarization of each of the first reference layer 65 and the second reference layer 75 may be fixed. When a current is supplied to each of the first SOT line 61 and the second SOT line 71, each of the first SOT line 61 and the second SOT line 71 may interact with the spin of a lattice due to a spin hall effect, and thus, a spin polarization phenomenon may occur in a direction perpendicular to a direction of the current. A magnetic polarization of each of the first storage layer 63 and the second storage layer 73 may be switched due to a spin hall effect of a corresponding one of the first SOT line 61 and the second SOT line 71.

In some embodiments, when electrical connection of the first terminal T11 is blocked using the first circuit 91 and a first write current is supplied using the third circuit 93 between the second terminal T12 and the third terminal T13 in a first direction, the first storage layer 63 may receive a spin torque in a second direction due to a spin hall effect, and the magnetic polarization of the first storage layer 63 may be switched to the second direction. The second direction may intersect the first direction. The second direction may be perpendicular to the first direction. When the first write current is supplied using the third circuit 93 between the second terminal T12 and the third terminal T13 in a direction opposite to the first direction, the magnetic polarization of the first storage layer 63 may be switched to a direction opposite to the second direction. Data of the first MTJ 67 may be read by applying a read current between the first terminal T11 and the third terminal T13 using the first circuit 91.

The first MTJ 67 may have a larger volume than the second MTJ 77. The first storage layer 63 may have a larger volume than the second storage layer 73. The first storage layer 63 may have a higher ratio of a major axis to a minor axis than the second storage layer 73. The first memory cell 69 may have a longer data retention time than the second memory cell 79.

In some embodiments, when electrical connection of the fourth terminal T21 is blocked using the second circuit 92 and a second write current is supplied using the fourth circuit 94 between the fifth terminal T22 and the sixth terminal T23 in a third direction, the second storage layer 73 may receive a spin torque in a fourth direction due to a spin hall effect, and the magnetic polarization of the second storage layer 73 may be switched to the fourth direction. The fourth direction may intersect the third direction. The fourth direction may be perpendicular to the third direction. When the second write current is supplied using the fourth circuit 94 between the fifth terminal T22 and the sixth terminal T23 in a direction opposite to the third direction, the magnetic polarization of the second storage layer 73 may be switched to a direction opposite to the fourth direction. Data of the second MTJ 77 may be read by applying a read current between the fourth terminal T21 and the sixth terminal T23 using the second circuit 92.

While the second write current is flowing through the second SOT line 71, the enhancing layer 72 may enhance a spin hall effect. The second MTJ 77 may have a smaller volume than the first MTJ 67. The second storage layer 73 may have a smaller volume than the first storage layer 63. The second storage layer 73 may have a lower ratio of a major axis to a minor axis than the first storage layer 63. The second memory cell 79 may have a higher write speed than the first memory cell 69. The second write current may be smaller than the first write current.

In some embodiments, some or all of the first circuit 91, the second circuit 92, the third circuit 93, the fourth circuit 94, and the control device 95 may be disposed in a third region 30 (see FIGS. 14 to 16). The control device 95 may independently control the first circuit 91, the second circuit 92, the third circuit 93, and the fourth circuit 94. The first memory cell 69 having a relatively long data retention time and the second memory cell 79 having a relatively high write speed may be provided in the substrate 51.

In some embodiments, although it is assumed that each of the first MTJ 67 and the second MTJ 77 is an in-plane MTJ (iMTJ), the inventive concept may be applied similarly to a case in which each of the first MTJ 67 and the second MTJ 77 is a pMTJ.

Referring to FIG. 20, the semiconductor device according to some embodiments of the inventive concept may include a plurality of terminals T11, T12, T13, T21, T22, and T23, a first circuit 96, a second circuit 97, a control device 98, the first memory cell 69, and the second memory cell 79. The first circuit 96 may be connected to a first terminal T11, a second terminal T12, and a third terminal T13. The second circuit 97 may be connected to a fourth terminal T21, a fifth terminal T22, and a sixth terminal T23. Each of the first circuit 96 and the second circuit 97 may correspond to a 3-terminal control circuit. By using the first circuit 96 and the second circuit 97, the magnetic polarization of the first storage layer 63 and the second storage layer 73 may be switched, and data of the first MTJ 67 and the second MTJ 77 may be read.

A method of forming the semiconductor device according to some embodiments of the inventive concept will be described with reference back to FIGS. 1 to 4.

The first SOT line 61 and the second SOT line 71 may be formed on the substrate 51. The formation of the first SOT line 61 and the second SOT line 71 may include a thin-film forming process and a patterning process. The enhancing layer 72 may be formed on the second SOT line 71.

In some embodiments, the formation of the enhancing layer 72 may include implanting ions into the second SOT line 71. The enhancing layer 72 may be formed in the second SOT line 71 along a surface of the second SOT line 71. The top surface of the enhancing layer 72 may be formed at substantially the same level as the top surface of the first SOT line 61.

In some embodiments, the formation of the enhancing layer 72 may include a thin-film forming process and a patterning process. The top surface of the enhancing layer 72 may be formed at a higher level than the top surface of the first SOT line 61.

In some embodiments, the formation of the enhancing layer 72 may include a selective deposition process.

The first MTJ 67 and the first electrode 68 may be formed on the first SOT line 61, and the second MTJ 77 and the second electrode 78 may be formed on the enhancing layer 72. The formation of the first MTJ 67, the second MTJ 77, the first electrode 68, and the second electrode 78 may include a plurality of thin-film forming processes and a plurality of patterning processes. In some embodiments, the enhancing layer 72 may be formed under the second MTJ 77.

According to example embodiments of the inventive concept, a first memory cell having a relatively long data retention time and a second memory cell having a relatively high write speed can be provided in a substrate (e.g., a single wafer). In some embodiments, a first memory cell having a relatively long data retention time and a second memory cell having a relatively high write speed may be formed in a single chip of a single wafer, which is surrounded by scribe lines. A semiconductor device, which is advantageous for process simplification and an increase in integration density and includes memory devices having different characteristics, can be implemented.

While some embodiments of the inventive concept have been described with reference to the accompanying drawings, it should be understood by those skilled in the art that various modifications may be made without departing from the scope of the inventive concept and without changing essential features thereof. Therefore, the above-described embodiments should be considered in a descriptive sense only and not for purposes of limitation. Thus, to the maximum extent allowed by law, the scope is to be determined by the broadest permissible interpretation of the following claims and their equivalents, and shall not be restricted or limited by the foregoing detailed description.

What is claimed is:

1. A semiconductor device comprising:
a first memory cell on a substrate; and
a second memory cell on the substrate and adjacent to the first memory cell,
wherein the first memory cell comprises:
a first reference layer;
a first storage layer;
a first tunnel layer between the first reference layer and the first storage layer; and
a first spin-orbit torque (SOT) line in contact with the first storage layer, and
wherein the second memory cell comprises:
a second reference layer;
a second storage layer;
a second tunnel layer between the second reference layer and the second storage layer;
a second SOT line adjacent to the second storage layer; and
an enhancing layer between the second storage layer and the second SOT line.

2. The semiconductor device of claim 1, wherein the first storage layer, the first tunnel layer, and the first reference layer are stacked along a vertical direction, and
wherein the first storage layer has a width in a horizontal direction greater than a width of the second storage layer in the horizontal direction, and the horizontal direction is perpendicular to the vertical direction.

3. The semiconductor device of claim 1, wherein the enhancing layer comprises a material having a higher spin-orbit coupling, a larger spin hall angle, or a higher spin/electrical current conductivity than the second SOT line.

4. The semiconductor device of claim 1, wherein the enhancing layer comprises tungsten, platinum, tantalum, tantalum oxide, platinum oxide, tungsten oxide, bismuth antimonide, bismuth selenide, hafnium, hafnium oxide, gold, copper gold, copper lead, copper platinum, copper bismuth, copper iridium, or a combination thereof.

5. The semiconductor device of claim 1, wherein the second SOT line comprises substantially the same material layer as the first SOT line.

6. The semiconductor device of claim 1, wherein the first storage layer, the first tunnel layer, and the first reference layer are stacked along a vertical direction, and
wherein the second SOT line and the first SOT line have an equal thickness in the vertical direction.

7. The semiconductor device of claim 6, wherein a surface of the enhancing layer facing the second storage layer is at a higher level than a surface of the first SOT line facing the first storage layer relative to the substrate.

8. The semiconductor device of claim 1, wherein the first storage layer, the first tunnel layer, and the first reference layer are stacked along a vertical direction, and
wherein the second SOT line has a thickness in the vertical direction less than a thickness of the first SOT line in the vertical direction.

9. The semiconductor device of claim 8, wherein a surface of the enhancing layer facing the second storage layer is substantially coplanar with a surface of the first SOT line facing the first storage layer.

10. The semiconductor device of claim 1, wherein the second memory cell is closer to an edge of the substrate than the first memory cell.

11. The semiconductor device of claim 1, wherein the second storage layer has a smaller volume than the first storage layer.

12. The semiconductor device of claim 1, wherein the second storage layer has a second ratio of a major axis to a minor axis, the first storage layer has a first ratio of a major axis to a minor axis, and the second ratio is lower than the first ratio.

13. The semiconductor device of claim 1, wherein each of the first reference layer, the second reference layer, the first storage layer, and the second storage layer comprises at least one magnetic layer.

14. The semiconductor device of claim 1, wherein the first SOT line and the second SOT line comprise tungsten, and
wherein the enhancing layer comprises bismuth antimonide.

15. The semiconductor device of claim 14, wherein each of the first storage layer and the second storage layer comprises a cobalt-iron layer, a cobalt-iron-boron layer, or a combination thereof.

16. The semiconductor device of claim 1, wherein the first memory cell has a longer data retention time than the second memory cell, and
wherein the second memory cell has a higher write speed than the first memory cell.

17. A semiconductor device comprising:
a first memory cell on a substrate; and
a second memory cell on the substrate and adjacent to the first memory cell,
wherein the first memory cell comprises:
a first reference layer;
a first storage layer;
a first tunnel layer between the first reference layer and the first storage layer; and
a first spin-orbit torque (SOT) line in contact with the first storage layer, and
wherein the second memory cell comprises:
a second reference layer;
a second storage layer;
a second tunnel layer between the second reference layer and the second storage layer; and
a second SOT line in contact with the second storage layer,
wherein the second SOT line comprises a material having a higher spin-orbit coupling, a larger spin hall angle, or a higher spin/electrical current conductivity than the first SOT line.

18. The semiconductor device of claim 17, wherein the first storage layer, the first tunnel layer, and the first reference layer are stacked along a vertical direction, and
wherein the second SOT line has a thickness in the vertical direction greater than a thickness of the first SOT line in the vertical direction.

19. A semiconductor device comprising:
a substrate comprising a first region and a second region adjacent to the first region;
a first memory cell in the first region on the substrate; and
a second memory cell in the second region on the substrate, and
wherein the first memory cell comprises:
a first reference layer;
a first storage layer;
a first tunnel layer between the first reference layer and the first storage layer; and
a first spin-orbit torque (SOT) line in contact with the first storage layer, and
wherein the second memory cell comprises:
a second reference layer;
a second storage layer;
a second tunnel layer between the second reference layer and the second storage layer;
a second SOT line adjacent to the second storage layer; and
an enhancing layer between the second storage layer and the second SOT line.

20. The semiconductor device of claim 19, wherein the second region is closer to an edge of the substrate than the first region.
